(19) United States
(12) Patent Application Publication
(10) Pub. No.: US 2023/0200253 A1
(43) Pub. Date: Jun. 22, 2023

(54) MULTIFUNCTIONAL MULTI-PIEZO MATERIAL HAVING PIEZOELECTRIC PROPERTIES AND MECHANOLUMINESCENCE PROPERTIES, AND MULTIFUNCTIONAL PIEZOELECTRIC BODY, MEMS DEVICE, ROBOT, STRAIN/FATIGUE/DAMAGE DIAGNOSIS DEVICE, AND NON-DESTRUCTIVE INSPECTION METHOD USING SAME

(71) Applicant: NATIONAL INSTITUTE OF ADVANCED INDUSTRIAL SCIENCE AND TECHNOLOGY, Chiyoda-Ku, Tokyo (JP)

(72) Inventors: Chao-Nan XU, Tosu-shi, Saga (JP); Ruiping Wang, Tsukuba-shi, Ibaraki (JP)

(21) Appl. No.: 17/998,769

(22) PCT Filed: Mar. 6, 2021
(86) PCT No.: PCT/JP2021/008846

§ 371 Date: Nov. 14, 2022

(30) Foreign Application Priority Data
Jul. 28, 2020 (JP) 2020-126975

(51) Int. Cl. H10N 30/853; H10N 30/20

(52) U.S. Cl. CPC H10N 30/8542; H10N 30/2047

(57) ABSTRACT

An object is to provide a multifunctional multi-piezo material having both high piezoelectric properties and high mechanoluminescence properties. It is a multi functional multi-piezo material represented by the chemical formula Li_{(1-X)(1+a)}Na_{X}NbO₃:M_{Y} (where M is at least one type of metal ion selected from transition metal ions), wherein the value of X is in the range from 0.10 or more to 0.98 or less, the value of Y is in the range from 0.0001 or more to 0.2 or less; and α is in the range from 0 or more. Such a multifunctional multi-piezo material has both high piezoelectric properties and high mechanoluminescence properties.

### TECHNICAL FIELD

The present invention relates to a multifunctional multi-piezo material which has both excellent piezoelectric properties and mechanoluminescence properties and is constituted by lithium niobate to which sodium and transition metal ions, for example, praseodymium are added, and a multifunctional piezoelectric body, a MEMS device, a robot, a strain/fatigue/damage diagnosis device, and a non-destructive inspection method using the same.

### BACKGROUND

Conventionally, lead zirconate titanate (PZT) has been widely used as a piezoelectric body material, which is to be utilized in sensors, actuators, and the like. However, PZT has a high relative dielectric constant, which causes a reduction in its performance index, and contains a large amount of lead (Pb) which is a toxic substance. Thus, in recent years, piezoelectric materials have been developed to replace PZT.

As regards to the above, as a mechanoluminescence material that can emit light with high sensitivity even by minute stress, for example, a substance in which some Li constituting a crystal body of LiNbO₃ are replaced with at least one type of metal ion selected from rare earth metal ions and transition metal ions has been proposed (see Patent Literature 1).

### CITATION LIST

### Patent Literature

Patent Literature 1: International Publication No. 2018/070072

### SUMMARY

### Technical Problem

Among the piezoelectric materials currently being developed, those that do not contain lead and have high piezoelectric properties have been proposed. However, there is a problem in which none of them has particular properties other than the piezoelectric properties.

In view of the above-mentioned circumstances, the present invention has an object of providing a multifunctional multi-piezo material having both high piezoelectric properties and high mechanoluminescence properties, and a multifunctional piezoelectric body, a MEMS device, a robot, a strain/strain/fatigue/damage diagnosis device, and a non-destructive inspection method using the same.

Note that, as described above, Patent Literature 1 discloses the mechanoluminescence material in which some Li constituting the crystal body of LiNbO₃ are replaced with at least one type of metal ion selected from the rare earth metal ions and the transition metal ions. However, as described below, the present invention exhibits higher mechanoluminescence properties (properties to emit light with higher intensity) than this substance and also exhibits high piezoelectric properties, making the present invention completely different from the disclosed materials.

### Solution to Problem

As a result of continuous extensive research on the above-mentioned problems, the inventor of the present invention has found the following innovative multifunctional multi-piezo material. The term “multi-piezo” described herein refers to a function of simultaneously exhibiting the strong mechanoluminescence properties and piezoelectric properties, discovered by the inventor of the present invention for the first time in the world.

A first aspect of the present invention for solving the above-mentioned problems is a multifunctional multi-piezo material represented by the chemical formula Li_{(1-X)(1+a)}Na_{X}NbO₃:M_{Y} (where M is at least one type of metal ion selected from transition metal ions), wherein a value of X is in a range from 0.10 or more to 0.98 or less, a value of Y is in a range from 0.0001 or more to 0.2 or less, and a is in a range from 0 or more. That is, in the present aspect, one type of transition metal ion may be included, or multiple types of transition metal ions may be included.

The term “transition metals” described herein refers to all metal elements (including rare earth metals) belonging to the groups from Group 3 to Group 12 of the periodic table.

Note that, if the value of Y is larger than 0.2, the transition metal ion cannot be dissolved as a solid solution and forms an impurity phase. As a result, it becomes difficult to produce the multifunctional multi-piezo material.

According to the first aspect, a multifunctional multi-piezo material having both high piezoelectric properties and high mechanoluminescence properties can be provided. The value of Y may fall within the range from 0.0005 or more to 0.1 or less because a multifunctional multi-piezo material having both higher piezoelectric properties and higher mechanoluminescence properties can be provided. In some embodiments, the value of Y may fall within the range from 0.001 or more and 0.05 or less because a multifunctional multi-piezo material having both much higher piezoelectric properties and much higher mechanoluminescence properties can be provided.

In addition, the concentration of Li contained in this multifunctional multi-piezo material may be a concentration that does not conform to stoichiometry. Specifically, because the multifunctional multi-piezo material according the present aspect (chemical formula: Li_{(1-X(1+α)}Na_{X}NbO₃:M_{Y}) has α being 0 or more, the concentration of Li contained therein may be higher than a compound represented by the chemical formula Li_{1-X}Na_{X}NbO₃:M_{Y} where α is zero. In other words, the multifunctional multi-piezo material according the present aspect may contain an abundant amount of Li (rich in Li content).

Such a multifunctional multi-piezo material containing an abundant amount of Li may be used because the material has much higher mechanoluminescence properties.

The term “mechanoluminescence properties” described herein refers to properties of emitting light (including visible light, ultraviolet light, and near infrared light) due to deformation caused by a mechanical external force, and the term “high mechanoluminescence properties” refers to light (mechanoluminescence) being emitted with high intensity.

A second aspect of the present invention is the multifunctional multi-piezo material according to the first aspect, wherein the value of X is in a range from 0.78 or more to 0.95 or less.

According to the second aspect, a multifunctional multi-piezo material having both much higher piezoelectric properties and much higher mechanoluminescence properties can be provided.

A third aspect of the present invention is the multifunctional multi-piezo material according to the first aspect, wherein the value of X is in a range from 0.83 or more to 0.91 or less.

According to the third aspect, a multifunctional multi-piezo material having both further higher piezoelectric properties and further higher mechanoluminescence properties can be provided.

A fourth aspect of the present invention is the multifunctional multi-piezo material according to the first aspect, wherein a lattice constant ratio c/a is in a range of 2.53 or less.

According to the fourth aspect, a multifunctional multi-piezo material having both much higher piezoelectric properties and much higher mechanoluminescence properties can be provided.

A fifth aspect of the present invention is the multifunctional multi-piezo material according to the second aspect, wherein a lattice constant ratio c/a is in a range of 2.52 or less.

According to the fifth aspect, a multifunctional multi-piezo material having both further higher piezoelectric properties and further higher mechanoluminescence properties can be provided.

A sixth aspect of the present invention is the multifunctional multi-piezo material according to the third aspect, wherein a lattice constant ratio c/a is in a range of 2.51 or less.

According to the sixth aspect, a multifunctional multi-piezo material having both particularly higher piezoelectric properties and particularly higher mechanoluminescence properties can be provided.

A seventh aspect of the present invention is the multifunctional multi-piezo material according to any one of the first to sixth aspects, wherein the value of a is in a range from more than 0 to 0.05 or less.

According to the seventh aspect, a multifunctional multi-piezo material having both further higher piezoelectric properties and further higher mechanoluminescence properties can be provided.

An eighth aspect of the present invention is the multifunctional multi-piezo material according to any one of the first to seventh aspects, wherein the crystal structure is a trigonal structure, an orthorhombic structure, or a mixture thereof.

According to the eighth aspect, a multifunctional multi-piezo material having both much higher piezoelectric properties and much higher mechanoluminescence properties can be provided.

A ninth aspect of the present invention is the multifunctional multi-piezo material according to any one of the first to eighth aspects, wherein M is one type of metal ion selected from rare earth metal ions. Specifically, in the present aspect, the multifunctional multi-piezo material may include one type of rare earth metal ion or multiple types of rare earth metal ions.

The term “rare earth metal” used herein refers to Sc (scandium), Y (yttrium), La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium).

According to the ninth aspect, a multifunctional multi-piezo material having both high piezoelectric properties and high mechanoluminescence properties can be provided.

A tenth aspect of the present invention is the multifunctional multi-piezo material according to any one of the first to eighth aspects, wherein M is Pr³⁺.

According to the tenth aspect, a multifunctional multi-piezo material having both high piezoelectric properties and high mechanoluminescence properties can be provided.

An eleventh aspect of the present invention is a multifunctional piezoelectric body including the multifunctional multi-piezo material according to any one of the first to tenth aspects.

According to the eleventh aspect, a multifunctional piezoelectric body having both high piezoelectric properties and high mechanoluminescence properties can be provided.

A twelfth aspect of the present invention is a MEMS device using the multifunctional multi-piezo material according to any one of the first to tenth aspects.

The term “MEMS device” used herein is not limited to particular devices as long as it is a micro-electro-mechanical system. Examples thereof include physical sensors such as a pressure sensor, an acceleration sensor, and a gyro sensor, actuators, microphones, fingerprint authentication sensors, and vibration generators.

According to the twelfth aspect, a MEMS device having both high piezoelectric properties and high mechanoluminescence properties can be provided.

A thirteenth aspect of the present invention is a robot or a strain/fatigue/damage diagnosis device for materials or structures using the multifunctional multi-piezo material according to any one of the first to tenth aspects.

The term “strain/fatigue/damage diagnosis device” used herein refers to a strain measurement device, a stress measurement device, a non-destructive inspection device, and the like for measuring the strain/fatigue/damage and the like of materials and structures.

According to the thirteenth aspect, it becomes possible to provide a robot having a movable part that emits light, which has not been available in the past, and a measurement device capable of accurately measuring strain, stress, and the like.

A fourteenth aspect of the present invention is a non-destructive inspection method for measuring the damage diagnosis of a structure using the multifunctional multi-piezo material according to any one of the first to tenth aspects.

The term “non-destructive inspection method” used herein refers to a known non-destructive inspection method and the like using a mechanoluminescence material and the like, without being particularly limited thereto.

According to the fourteenth aspect, a non-destructive inspection method utilizing both high piezoelectric properties and high mechanoluminescence properties can be provided.

### BRIEF DESCRIPTION OF DRAWINGS

FIG. 1 is a schematic cross-sectional view of a multifunctional multi-piezo material thin film according to a first embodiment.

FIG. 2 is a graph showing the relationship between the concentration X of Na, and the piezoelectric coefficient d₃₃ and the electromechanical coupling constant kp of the multifunctional multi-piezo material thin films in Example 1.

FIG. 3 is a graph showing the relationship between the concentration X of Na and the intensity of the mechanoluminescence of the multifunctional multi-piezo material thin films in Example 1.

FIG. 4 is a graph showing the relationship between the concentration X of Na and the intensity of the mechanoluminescence of the multifunctional multi-piezo material thin films in Example 1.

FIG. 5 is a graph showing the relationship between the concentration X of Na and the lattice constant a of the multifunctional multi-piezo material thin films in Example 1.

FIG. 6 is a graph showing the relationship between the concentration X of Na and the lattice constant c of the multifunctional multi-piezo material thin films in Example 1.

FIG. 7 is a graph showing the relationship between the concentration X of Na and the lattice constant ratio c/a of the multifunctional multi-piezo material thin films in Example 1.

FIG. 8 is a graph showing the relationship between the load applied to the multifunctional multi-piezo material thin films in Example 2 and the emission intensity of the mechanoluminescence.

FIG. 9 is a graph showing the relationship between α of the multifunctional multi-piezo material thin films in Example 2 and the photoluminescence as well as the mechanoluminescence (piezoluminescence).

FIG. 10 is a graph showing X-ray diffraction (XRD) measurement results of the respective multifunctional multi-piezo materials in Example 2.

FIG. 11 is a table showing respective multifunctional multi-piezo materials in Example 3 and the emission intensity of the mechanoluminescence of each of them.

### DETAILED DESCRIPTION

Hereinafter, embodiments using a multifunctional multi-piezo material according to the present invention will be described with reference to the accompanying drawings. Needless to say, the present invention is not limited to the following embodiments, and may be embodied not only as a thin film.

### First Embodiment

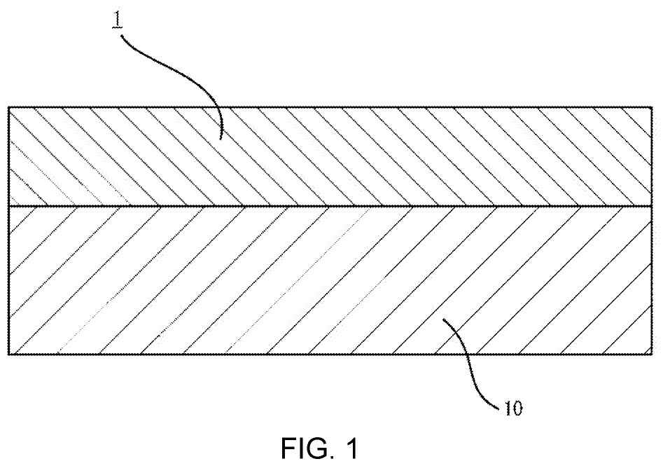

FIG. 1 is a schematic cross-sectional view of a multifunctional device (multifunctional multi-piezo material thin film) using a multifunctional multi-piezo material according to the embodiment. As shown in FIG. 1, a multifunctional multi-piezo material thin film 1 is formed on a substrate 10. Although the thickness of the multifunctional multi-piezo material thin film 1 is not particularly limited, the thickness may fall in the range from 0.1 μm to 100 μm because its adhesion is excellent, or the thickness may fall in the range from 1 μm to 50 μm because its adhesion is excellent.

The thickness, material, and the like of the substrate 10 are not particularly limited as long as the multifunctional multi-piezo material thin film 1 can be formed on the surface of the substrate 10. Examples of the substrate 10 include a heat-resistant alloy such as silicon and Inconel, and a resin film such as polyimide.

The multifunctional multi-piezo material thin film 1 is represented by the chemical formula Li_{(1-X)(1+a)}Na_{X}NbO₃:M_{Y} (where M is at least one type of metal ion selected from transition metal ions) in which the value of X of Na is in the range from 0.10 or more to 0.98 or less, the value of Y of the transition metal ion M is in the range from 0.0001 or more to 0.2 or less, and a is in the range from 0 or more, and is composed of lithium niobate to which at least one type of metal ion selected from sodium (Na) and transition metal ions (M).

The multifunctional multi-piezo material thin film 1 constituted by the above-mentioned multifunctional multi-piezo material has a higher piezoelectric charge constant d₃₃ than a lithium niobate piezoelectric thin film to which Na and M are not added, and exhibits high mechanoluminescence properties. Furthermore, this multifunctional multi-piezo material exhibits a unique special property of repeatedly emitting light with high sensitivity using an extremely small force (e.g., force levels of 1 to 9 pN).

In some embodiments, multifunctional multi-piezo material thin film 1 which has the value of X in the range from 0.78 or more to 0.95 or less in the above-mentioned chemical formula may be used. The multi-piezo material thin film 1 with such a configuration has much higher d₃₃ and electromechanical coupling constant kp, and much higher mechanoluminescence properties.

Furthermore, a multifunctional multi-piezo material thin film 1 which has the value of X in the range from 0.83 or more to 0.91 or less in the above-mentioned chemical formula may be used. The multifunctional multi-piezo material thin film 1 with such a configuration has further higher piezoelectric charge constant d₃₃ and electromechanical coupling constant kp, and further higher mechanoluminescence properties.

Furthermore, the above-mentioned multifunctional multi-piezo material thin film 1 having a crystal structure of a trigonal R3c phase, orthorhombic P21ma, or a mixture thereof has a lattice constant ratio c/a may be in the range of 2.53 or less, or in the range of 2.52 or less, or in the range of 2.51 or less. The multifunctional multi-piezo material thin film 1 having such a lattice constant ratio c/a has a further higher piezoelectric charge constant d₃₃ and electromechanical coupling constant kp and exhibits further higher mechanoluminescence properties.

Furthermore, a MEMS device using these multifunctional multi-piezo material thin films 1 has a high piezoelectric charge constant d₃₃ and electromechanical coupling constant kp and exhibits high mechanoluminescence properties, providing an unprecedented MEMS device utilizing these functions. Note that the configuration of the MEMS device is not particularly limited, and the MEMS device can be produced by a known configuration.

Next, a method for producing the multifunctional multi-piezo material thin film 1 according to the present embodiment will be described by taking the case of using Pr′ as the added metal M as an example. The multifunctional multi-piezo material thin film 1 can be produced using a production method such as a sputtering method or a vapor deposition method in the same manner as a general piezoelectric thin film, but it can also be produced using a production method described below.

### Example 1

First, a multifunctional multi-piezo material (Li_{1-X}Na_{X}NbO₃:Pr_{Y}) was prepared by a solid-phase synthesis method. Specifically, Nb₂O₅, Li₂CO₃, Na₂CO₃, and Pr₂O₃ were weighed so as to obtain target composition ratios, and then mixed and pulverized in an agate mortar to obtain mixtures having different concentration X of Na. Note that X was adjusted to cover the entire range from 0 to 100. Furthermore, the concentration Y of Pr in these multifunctional multi-piezo materials was 0.002.

Next, these mixtures were fired in an electric furnace to obtain a multifunctional multi-piezo material thin film from each mixture. For firing, each mixture was molded in a pellet shape with a hydraulic machine and fired using a muffle furnace. The firing was performed under conditions of 1050° C. for 8 hours in the air with a temperature rise rate of 3° C./min.

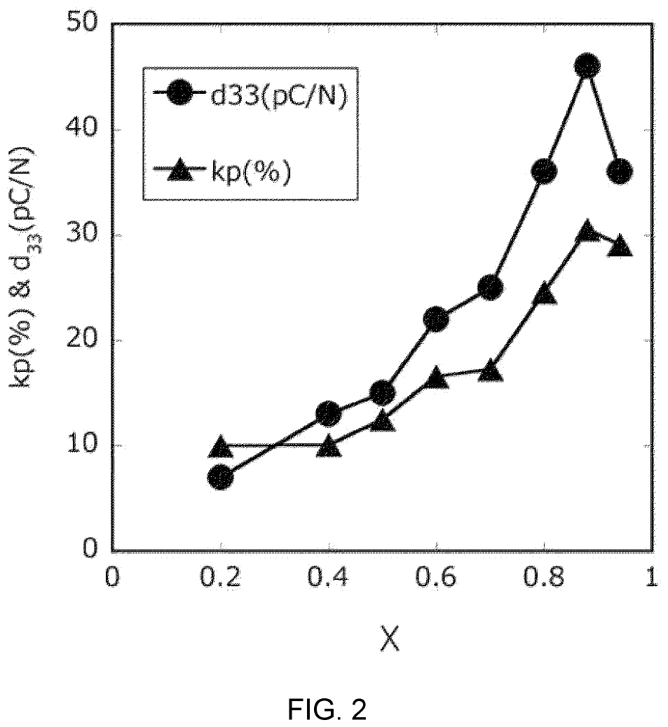

FIG. 2 shows the relationship between the concentration X of Na, and the piezoelectric charge constant d₃₃ and the electromechanical coupling constant kp for each multifunctional multi-piezo material thin film (thickness of 1 mm) obtained by using the above-mentioned production method. In FIG. 2, the round marks indicate the piezoelectric charge constant d₃₃ and the triangular marks indicate the electromechanical coupling constant kp. Note that the piezoelectric charge constant d₃₃ was measured using a d₃₃ meter and the electromechanical coupling constant kp was measured using an LCR meter.

As can be seen from in FIG. 2, it was found that as the concentration X of Na becomes higher (increases), the values of the piezoelectric charge constant d₃₃ and the electromechanical coupling constant kp increase, and peak at the concentration X of Na being 0.88. Furthermore, it was found that as the concentration X of Na increases, these values decrease.

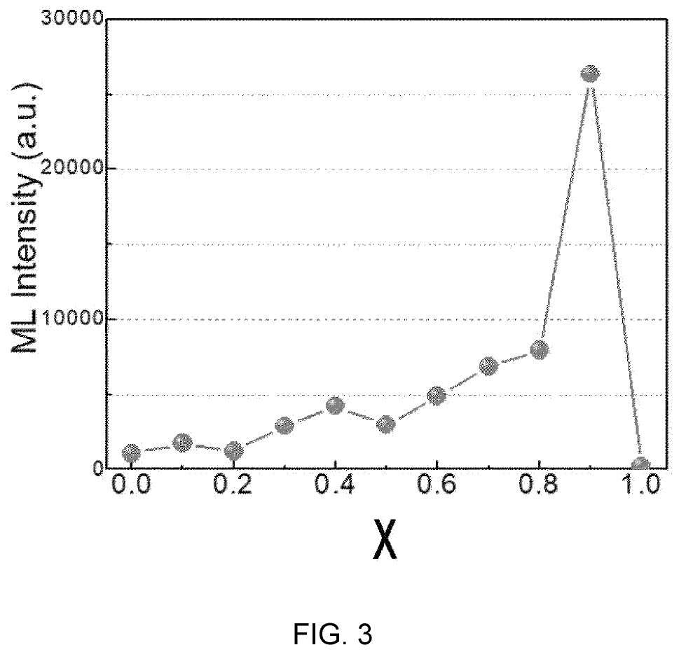

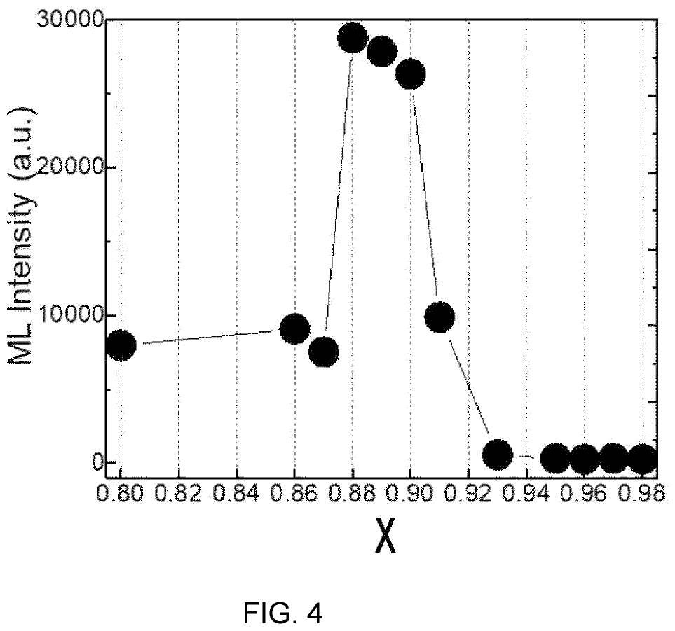

Next, the mechanoluminescence properties of each multifunctional multi-piezo material thin film were evaluated. For the mechanoluminescence properties, in accordance with the conventional cylindrical test piece shape, the multifunctional multi-piezo material thin film obtained in the above was embedded in an epoxy resin, and then the embedded multifunctional multi-piezo material thin film was placed in the center of the surface of a cylindrical molded body and molded into a cylindrical shape with a diameter of 25 mm and a thickness of 10 mm, thereby producing a cylindrical test piece. Regarding the cylindrical test piece thus obtained, the relationship between the concentration X of Na and the intensity of the mechanoluminescence (ML Intensity) is shown in FIG. 3 and FIG. 4. The wavelength of the mechanoluminescence is from 600 nm to 650 nm. Note that the emission intensity of the mechanoluminescence was measured using a mechanoluminescence measurement device disclosed in Japanese Patent Application Laid-Open No. 2001-215157 or International Publication No. 2005/097946.

As can be seen from FIG. 3, it was found that as the concentration X of Na increases, the emission intensity of the mechanoluminescence increases like the piezoelectric charge constant d₃₃, and peaks at the concentration X of Na being 0.88. Furthermore, it was found that as the concentration X of Na increases, these values decrease.

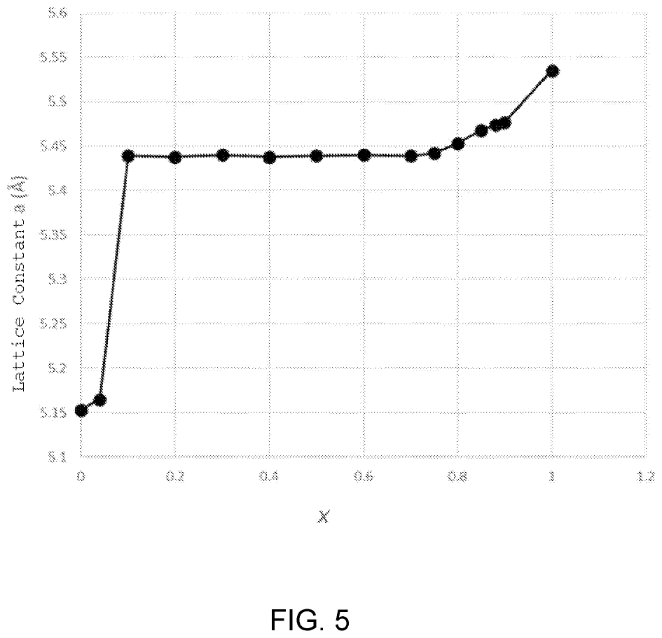

FIG. 5 shows the relationship between the concentration X of Na and the lattice constant a of the multifunctional multi-piezo material thin film for each multifunctional multi-piezo material thin film.

As can be seen from FIG. 5, as the concentration X of Na increases to 0.1, the value of the lattice constant a rises sharply. After that, the value of the lattice constant a becomes substantially constant until the concentration X of Na reaches 0.7. However, it was found that when the concentration X of Na exceeds 0.7, the value of the lattice constant a increases as the concentration X of Na increases.

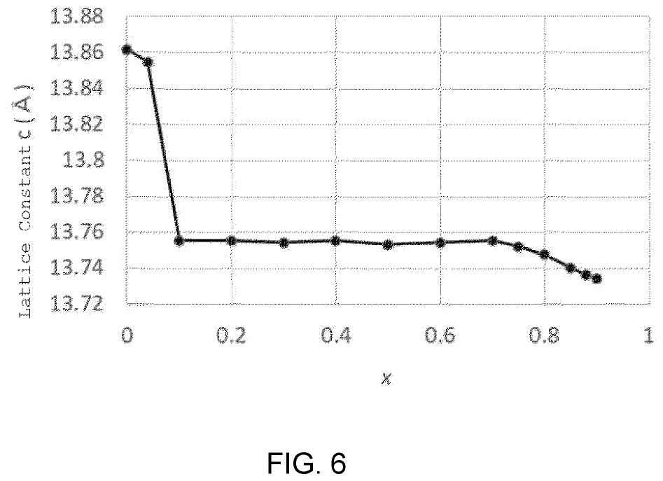

FIG. 6 shows the relationship between the concentration X of Na and the lattice constant c of the multifunctional multi-piezo material thin film for each multifunctional multi-piezo material thin film.

As can be seen from FIG. 6, as the concentration X of Na increases to 0.1, the value of the lattice constant c decreases sharply. After that, the value of the lattice constant c becomes substantially constant until the concentration X of Na reaches 0.7. However, it was found that when the concentration X of Na exceeds 0.7, the value of the lattice constant c decreases as the concentration X of Na increases.

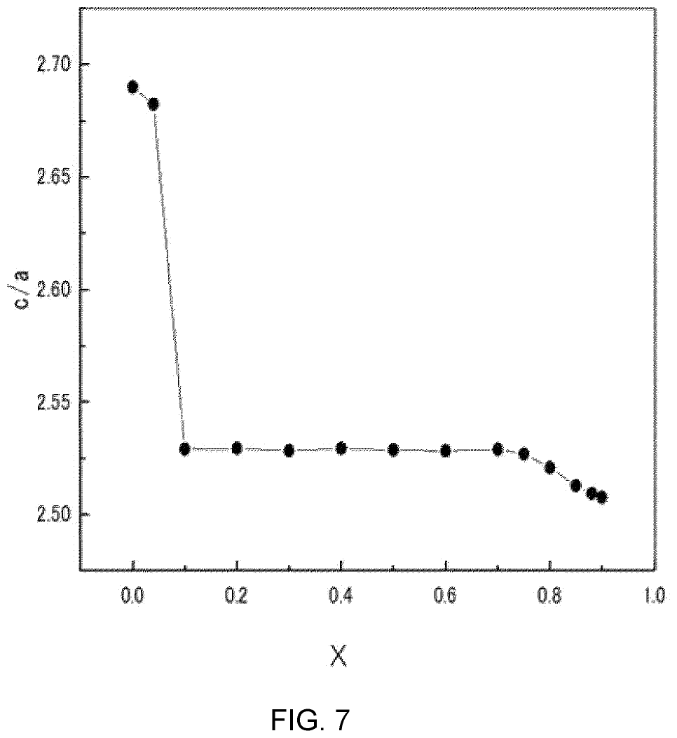

FIG. 7 shows the relationship between the concentration X of Na and the lattice constant ratio (c/a) of the multifunctional multi-piezo material thin film in the trigonal structure.

As can be seen from FIG. 7, as the concentration X of Na increases to 0.1, the value of the lattice constant ratio c/a decreases sharply. After that, the value of the lattice constant ratio c/a becomes substantially constant until the concentration X of Na reaches 0.7. However, it was found that when the concentration X of Na exceeds 0.7, the value of the lattice constant ratio (c/a) decreases as the concentration X of Na increases.

In addition, it was found that when the concentration X of Na is in the range from 0.0 to 0.9, the multifunctional multi-piezo material has a trigonal structure and the space group (crystal space group) is R3c. Furthermore, it was found that when the concentration X of Na becomes 0.95 or more, the space group becomes P21ma.

### Second Embodiment

Although the multifunctional multi-piezo material Li_{(1-X)(1+α)}Na_{X}NbO₃:M_{Y} in the case of α=0 has been described in the example of the first embodiment, the present invention is not limited thereto. For example, a may be greater than 0 (which may be rich in Li content).

The multifunctional multi-piezo materials in which α is in the range from more than 0 to less than or equal to 0.05 may be used because they have high mechanoluminescence properties. The multifunctional multi-piezo materials in which α is in the range from more than 0 to less than or equal to 0.03 may be used because they have higher mechanoluminescence properties. In some embodiments, the multifunctional multi-piezo materials in which α is in the range from more than 0.005 to less than or equal to 0.015 may be used because they have further higher mechanoluminescence properties. These multifunctional multi-piezo materials naturally have piezoelectric properties.

Such a Li-rich multifunctional multi-piezo material can be produced by weighing the target compositional ratios of Nb₂O₅, Li₂CO₃, Na₂CO₃ and Pr₂O₃ such that the concentration of Li is higher than the concentration shown by the chemical formula Li_{1-X}Na_{X}NbO₃:M_{Y} where α=0, and performing the same procedure as in Example 1 hereafter.

### Example 2

Multifunctional multi-piezo materials represented by Li_{0.12}Na_{0.88}NbO₃:Pr_{0.002}, Li_{0.13}Na_{0.88}NbO₃:Pr_{0.002}, Li_{0.15}Na_{0.88}NbO₃:Pr_{0.002} and Li_{0.17}Na_{0.88}NbO₃:Pr_{0.002}, respectively, were prepared using the above-described production method.

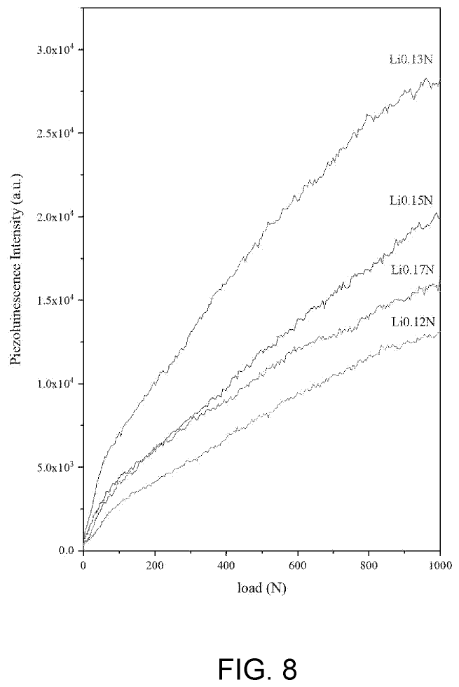

First, each of the multifunctional multi-piezo materials was embedded in an epoxy resin to produce a cylindrical test piece with a diameter of 25 mm and a thickness of 10 mm. Then, the emission intensity of the mechanoluminescence when a load was applied was measured. The results are shown in FIG. 8. In the following figures, Li_{0.12}N denotes Li_{1.12}Na_{0.88}NbO₃:Pr_{0.002}, Li_{0.13}N denotes Li_{0.13}Na_{0.88}NbO₃:Pr_{0.002}, Li_{0.15}N denotes Li_{0.15}Na_{0.88}NbO₃:Pr_{0.002}, and Li_{0.17}N denotes Li_{0.17}Na_{0.88}NbO₃:Pr_{0.002}.

As can be seen from FIG. 8, it was found that the Li-rich multifunctional multi-piezo material has the higher emission intensity of the mechanoluminescence than the non-Li-rich material (where a=0).

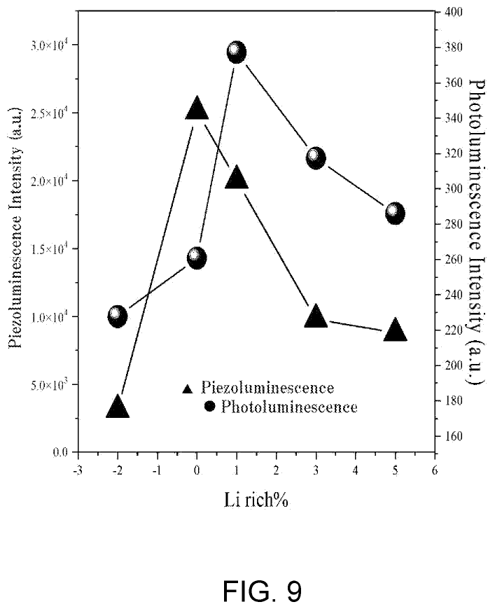

Next, FIG. 9 shows the relationship between a of the multifunctional multi-piezo material thin film and the emission intensity of the mechanoluminescence when a load of 100 N was applied. As can be seen from FIG. 9, it was found that Li_{0.13}N has the highest emission intensity of the mechanoluminescence.

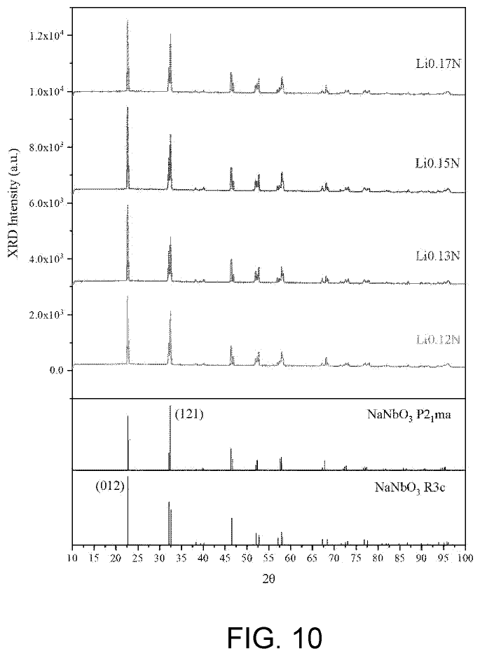

Furthermore, FIG. 10 shows X-ray diffraction (XRD) measurement results of each multifunctional multi-piezo material. Note that RINT-2000 (manufactured by Rigaku Corp.) was used as the X-ray diffractometer. As can be seen from FIG. 10, it was found that each multifunctional multi-piezo material is constituted by a mixed phase of the trigonal R3c phase and the orthorhombic P21ma.

### Third Embodiment

In the above-described embodiment, Pr³⁺ is used as M, but the present invention is not limited thereto. Similar results can be obtained even when a transition metal ion other than Pr³⁺ is used as M.

### Example 3

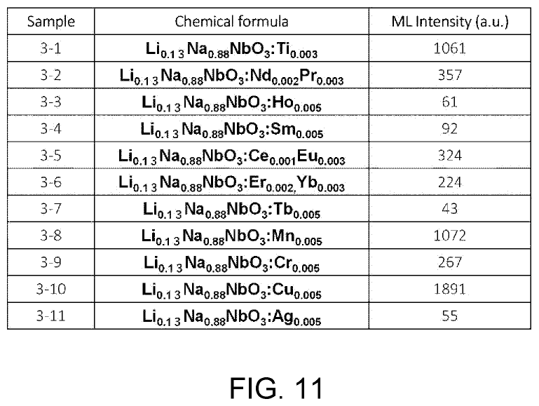

Multifunctional multi-piezo materials were prepared by adding (doping) transition metals other than Pr as M, and the intensity of the mechanoluminescence of each of the multifunctional multi-piezo materials was measured. These multifunctional multi-piezo materials were produced in the same manner as in Example 1 described above, using TiO₂, Nd₂O₃, Ho₂O₃, Sm₂O₃, CeO₂, Eu₂O₃, Er₂O₃, Yb₂O₃, Tb₄O₇, MnO₂, Cr₂O₃, Cu₂O, or Ag₂O together with Pr₂O₃ or instead of Pr₂O₃. Then, the intensity of the mechanoluminescence of each of the obtained multifunctional multi-piezo materials is shown in FIG. 11. These multifunctional multi-piezo materials naturally also have piezoelectric properties.

As can be seen from FIG. 11, it was found that these multifunctional multi-piezo materials have the same effects as the multifunctional multi-piezo material according to the above-described embodiment.

### Other Embodiments

In the above-described embodiments, the multifunctional multi-piezo material thin films were produced using only the multifunctional multi-piezo materials, but the present invention is not limited thereto.

A multifunctional multi-piezo material thin film may be produced by, for example, mixing the multifunctional multi-piezo material with an organic material such as a resin, a plastic, or a rubber, or an inorganic material such as glass or ceramic, and then using the above-described production method.

Furthermore, a multifunctional multi-piezo material thin film made of the multifunctional multi-piezo material and an organic material may be produced, for example, by mixing the multifunctional multi-piezo material and an organic material such as a resin or a rubber by a known method.

In this manner, a multifunctional multi-piezo thin film made of the multifunctional multi-piezo material, an inorganic material, and an organic material, or a mixed material composed of an inorganic material and an organic material may be produced. The inorganic material and the organic material mixed with the multifunctional multi-piezo material are not limited to particular materials. The concentration of the multifunctional multi-piezo material included in the multifunctional multi-piezo thin film is not particularly limited.

Even with such a multifunctional multi-piezo material thin film, the same effects as those of the multifunctional multi-piezo material thin films according to the above-described embodiments can be obtained.

Furthermore, the present invention is not limited to those described above. A multifunctional piezoelectric body may be constituted by including the above-mentioned multifunctional multi-piezo material. This multifunctional piezoelectric body exhibits both high piezoelectric properties and high mechanoluminescence properties. Note that the multifunctional piezoelectric body may include a component other than the multifunctional multi-piezo material, and such a component is not particularly limited.

Furthermore, the above-mentioned multifunctional multi-piezo materials may be used to constitute a robot or a strain/fatigue/damage diagnosis device for materials or structures. As a configuration of the robot and the strain/fatigue/damage diagnosis device, a known configuration for producing a functional device such as a sensor for sensing, a waveguide for communication control, and an actuator for action can be adopted. In addition, the above-mentioned multifunctional multi-piezo material can be used as a film or sheet sensor in a non-destructive inspection method for measuring the damage diagnosis of a mechanical part, an implant product, and structures, for example, infrastructures such as a bridge, a tunnel, and a pipeline. Examples of the non-destructive inspection method include a known non-destructive inspection method, using the mechanoluminescence material and the like, such as fatigue detection, stress concentration prediction, or remaining life diagnosis.

### REFERENCE SIGNS LIST

1 multifunctional multi-piezo material thin film
10 substrate

1. A multifunctional multi-piezo material represented by the chemical formula Li_{(1-X)(1+a)}Na_{X}NbO₃:M_{Y} (where M is at least one type of metal ion selected from transition metal ions), wherein a value of X is in a range from 0.10 or more to 0.98 or less, a value of Y is in a range from 0.0001 or more to 0.2 or less, and a is in a range from 0 or more.

2. The multifunctional multi-piezo material according to claim 1, wherein the value of X is in a range from 0.78 or more to 0.95 or less.

3. The multifunctional multi-piezo material according to claim 1, wherein the value of X is in a range from 0.83 or more to 091 or less.

4. The multifunctional multi-piezo material according to claim 1, wherein a lattice constant ratio c/a is in a range of 2.53 or less.

5. The multifunctional multi-piezo material according to claim 2, wherein a lattice constant ratio c/a is in a range of 2.52 or less.

6. The multifunctional multi-piezo material according to claim 3, wherein a lattice constant ratio c/a is in a range of 2.51 or less.

7. The multifunctional multi-piezo material according to claim 1, wherein a value of a is in a range from more than 0 to 0.05 or less.

8. The multifunctional multi-piezo material according to claim 1, wherein a crystal structure is a trigonal structure, a trigonal structure, an orthorhombic structure, or a mixture thereof.

9. The multifunctional multi-piezo material according to claim 1, wherein M is one type of metal ion selected from rare earth metal ions.

10. The multifunctional multi-piezo material according to claim 1, wherein M is Pr3+.

11. A multifunctional piezoelectric body comprising the multifunctional multi-piezo material according to claim 1.

12. A MEMS device using the multifunctional multi-piezo material according to claim 1.

13. A robot or a strain/fatigue/damage diagnosis device for material or structure using the multifunctional multi-piezo material according to claim 1.

14. A non-destructive inspection method for measuring damage diagnosis of a structure using the multifunctional multi-piezo material according to claim 1.
